(19) United States
(12) Patent Application Publication
(10) Pub. No.: US 2026/0023106 A1
(43) Pub. Date: Jan. 22, 2026

(54) TEST APPARATUS AND METHOD FOR TESTING PCBA OF A DIAGNOSTIC DEVICE

(71) Applicant: Church & Dwight Co., Inc., Princeton, NJ (US)

(72) Inventors: Andy Sturman, San Diego, CA (US); Shang Li, Princeton JCT, NJ (US); Ming Zeng, Princeton, NJ (US); Robert Amariti, Voorhees, NJ (US)

(21) Appl. No.: 19/180,620

(22) Filed: Apr. 16, 2025

Related U.S. Application Data
(60) Provisional application No. 63/635,293, filed on Apr. 17, 2024.

(51) Int. Cl. G01R 31/28

(52) U.S. Cl. CPC G01R 31/2829

(57) ABSTRACT

Test apparatus and method for testing a printed circuit board assembly (PCBA) of a diagnostic device are disclosed. The apparatus controls a light source of the PCBA of the diagnostic device to operate at a first current level. The apparatus measures a first collector current of a first photo sensor of the PCBA of the diagnostic device. The apparatus measures a first collector current of a second photo sensor of the PCBA of the diagnostic device. The apparatus controls the light source of the PCBA of the diagnostic device to operate at a second current level. The apparatus measures a second collector current of the first photo sensor of the PCBA of the diagnostic device. The apparatus measures a second collector current of the second photo sensor of the PCBA of the diagnostic device. The apparatus determines an error value based on the measured collector currents.

### CROSS-REFERENCE TO RELATED APPLICATIONS

The present application claims priority to U.S. Provisional Patent Application No. 63/635,293, filed Apr. 17, 2024, the disclosure of which is incorporated herein by reference in its entirety.

### TECHNICAL FIELD

The application generally relates to test apparatus and method. More particularly, the application relates to test apparatus and method for testing a printed circuit board assembly (PCBA) of a diagnostic device.

### BACKGROUND

Diagnostic devices have been widely used to detect the presence of various substances in body fluids, such as urine, saliva, blood, etc. Some applications for these devices include blood typing, pregnancy testing, and many types of urinalysis. Typically, a diagnostic device is bundled with an over-the-counter (OTC) diagnostic test kit that enables a consumer to self-diagnose, for example, pregnancy, ovulation, sexually transmitted infections, and other bacterial infections or clinical abnormalities that result in the presence of an antigenic marker substance in a body fluid.

The diagnostic device generally includes a printed circuit board (PCB) or PCBA with interconnected electrical components, for example, diodes, transistors, capacitors, resistors, microprocessors/microcontrollers, etc. Unfortunately, some of these components can be defective after fabrication, and therefore, thorough testing of the PCBA is needed to ensure its reliability before device assembly.

### SUMMARY OF THE DISCLOSURE

The present disclosure relates to a test apparatus, such as a diagnostic device (e.g., a pregnancy test device), comprising a printed circuit board assembly (PCBA) and a method for determining whether the PCBA is in a sufficiently functional condition to proceed with device assembly. The test apparatus can be configured to measure one or more parameters of components of the PCBA by evaluating a measured difference in the one or more parameters, and this difference can be used to determine whether the PCBA is acceptable or rejectable for device assembly.

In one or more embodiments, the present disclosure relates to a test apparatus for testing a printed circuit board assembly (PCBA) of a diagnostic device. In particular, the test apparatus can comprise: a processor; and a memory coupled to the processor to store instructions, which when executed by the processor, cause the test apparatus to: control a light source of the PCBA of the diagnostic device to operate at a first current level; measure a first collector current of a first photo sensor of the PCBA of the diagnostic device; measure a first collector current of a second photo sensor of the PCBA of the diagnostic device; control the light source of the PCBA of the diagnostic device to operate at a second current level; measure a second collector current of the first photo sensor of the PCBA of the diagnostic device; measure a second collector current of the second photo sensor of the PCBA of the diagnostic device; and determine an error value based on the measured first collector current of the first photo sensor, the measured first collector current of the second photo sensor, the measured second collector current of the first photo sensor, and the measured second collector current of the second photo sensor. In further embodiments, the test apparatus may be defined in relation to one or more of the following statements, which statements can be combined in any number or order.

The instructions, which when executed by the processor, further can cause the test apparatus to: determine whether the error value is less than a threshold value, where the error value is an absolute error value; in response to determining that the error value is less than the threshold value, send a first signal to illuminate a first light source of the test apparatus to indicate a pass.

The instructions, which when executed by the processor, further can cause the test apparatus to: in response to determining that the error value is greater than or equal to the threshold value, send a second signal to illuminate a second light source of the test apparatus to indicate a failure.

The instructions, which when executed by the processor, further can cause the test apparatus to: store the measured first collector current of the first photo sensor as a first collector current value; store the measured first collector current of the second photo sensor as a second collector current value; store the measured second collector current of the first photo sensor as a third collector current value; and store the measured second collector current of the second photo sensor as a fourth collector current value.

To determine the error value, the instructions, which when executed by the processor, can cause the test apparatus to: determine the error value in accordance with the following:

$$\vert Pct\_Err \vert = ( 100 * ( {I}_{Q 3\_ Low} / {I}_{Q 3} ) ) - ( 100 * ( {I}_{Q 1 \_ Low} / {I}_{Q 1} ) ) ;$$

wherein: |Pct_Err| is an absolute value of the error value; I_{Q1_Low} is the first collector current value; I_{Q3_Low} is the second collector current value; I_{Q1} is the third collector current value; and I_{Q3} is the fourth collector current value.

The second current level can be higher than the first current level.

The instructions, which when executed by the processor, further can cause the test apparatus to: apply a supply voltage to the PCBA of the diagnostic device; and apply a voltage potential to a processor or microcontroller on the PCBA of the diagnostic device to switch the processor or microcontroller on the PCBA of the diagnostic device to a programming mode.

In one or more embodiments, the present disclosure relates to a non-transitory machine-readable medium having instructions stored therein, which when executed by a processor, can cause the processor to perform operations. In particular, the operations can comprise: controlling a light source of a printed circuit board assembly (PCBA) of a diagnostic device to operate at a first current level; measuring a first collector current of a first photo sensor of the PCBA of the diagnostic device; measuring a first collector current of a second photo sensor of the PCBA of the diagnostic device; controlling the light source of the PCBA of the diagnostic device to operate at a second current level; measuring a second collector current of the first photo sensor of the PCBA of the diagnostic device; measuring a second collector current of the second photo sensor of the PCBA of the diagnostic device; and determining an error value based on the measured first collector current of the first photo sensor, the measured first collector current of the second photo sensor, the measured second collector current of the first photo sensor, and the measured second collector current of the second photo sensor. In further embodiments, the non-transitory machine-readable medium may be defined in relation to one or more of the following statements, which statements can be combined in any number or order.

The operations further can comprise: determining whether the error value is less than a threshold value, where the error value is an absolute error value; in response to determining that the error value is less than the threshold value, sending a first signal to illuminate a first light source of a test apparatus to indicate a pass.

The operations further can comprise: in response to determining that the error value is greater than or equal to the threshold value, sending a second signal to illuminate a second light source of the test apparatus to indicate a failure.

The operations further can comprise: storing the measured first collector current of the first photo sensor as a first collector current value; storing the measured first collector current of the second photo sensor as a second collector current value; storing the measured second collector current of the first photo sensor as a third collector current value; and storing the measured second collector current of the second photo sensor as a fourth collector current value.

Determining the error value can comprise: determining the error value in accordance with the following:

$$\vert Pct\_Err \vert = ( 100 * ( {I}_{Q 3\_ Low} / {I}_{Q 3} ) ) - ( 100 * ( {I}_{Q 1 \_ Low} / {I}_{Q 1} ) ) ;$$

wherein: |Pct_Err| is an absolute value of the error value; I_{Q1_Low} is the first collector current value; I_{Q3_Low} is the second collector current value; I_{Q1} is the third collector current value; and I_{Q3} is the fourth collector current value.

The second current level can be higher than the first current level.

The operations further can comprise: applying a supply voltage to the PCBA of the diagnostic device; and applying a voltage potential to a processor or microcontroller on the PCBA of the diagnostic device to switch the processor or microcontroller on the PCBA of the diagnostic device to a programming mode.

In one or more embodiments, the present disclosure relates to a computer-implemented method of testing a printed circuit board assembly (PCBA) of a diagnostic device. In particular, the method can comprise: controlling a light source of the PCBA of the diagnostic device to operate at a first current level; measuring a first collector current of a first photo sensor of the PCBA of the diagnostic device; measuring a first collector current of a second photo sensor of the PCBA of the diagnostic device; controlling the light source of the PCBA of the diagnostic device to operate at a second current level; measuring a second collector current of the first photo sensor of the PCBA of the diagnostic device; measuring a second collector current of the second photo sensor of the PCBA of the diagnostic device; and determining an error value based on the measured first collector current of the first photo sensor, the measured first collector current of the second photo sensor, the measured second collector current of the first photo sensor, and the measured second collector current of the second photo sensor. In further embodiments, the computer-implemented method may be defined in relation to one or more of the following statements, which statements can be combined in any number or order.

The method further can comprise: determining whether the error value is less than a threshold value, where the error value is an absolute error value; in response to determining that the error value is less than the threshold value, sending a first signal to illuminate a first light source of a test apparatus to indicate a pass.

The method further can comprise: in response to determining that the error value is greater than or equal to the threshold value, sending a second signal to illuminate a second light source of the test apparatus to indicate a failure.

The method further can comprise: storing the measured first collector current of the first photo sensor as a first collector current value; storing the measured first collector current of the second photo sensor as a second collector current value; storing the measured second collector current of the first photo sensor as a third collector current value; and storing the measured second collector current of the second photo sensor as a fourth collector current value.

Determining the error value can comprise: determining the error value in accordance with the following:

$$\vert Pct\_Err \vert = ( 100 * ( {I}_{Q 3\_ Low} / {I}_{Q 3} ) ) - ( 100 * ( {I}_{Q 1 \_ Low} / {I}_{Q 1} ) ) ;$$

wherein: |Pct_Err| is an absolute value of the error value; I_{Q1_Low} is the first collector current value; I_{Q3_Low} is the second collector current value; I_{Q1} is the third collector current value; and I_{Q3} is the fourth collector current value.

The method further can comprise: applying a supply voltage to the PCBA of the diagnostic device; and applying a voltage potential to a processor or microcontroller on the PCBA of the diagnostic device to switch the processor or microcontroller on the PCBA of the diagnostic device to a programming mode.

### BRIEF DESCRIPTION OF THE DRAWINGS

FIG. 1 is a block diagram illustrating an example PCBA test system according to an embodiment.

FIG. 2 is a schematic diagram illustrating an example PCBA test system according to an embodiment.

FIGS. 3A-3B are schematic diagrams of an example PCBA of a test device according to an embodiment.

FIG. 4 is a flow diagram illustrating a process for testing a PCBA of a diagnostic device according to an embodiment.

FIG. 5 is a flow diagram illustrating another process for testing the PCBA of the diagnostic device according to an embodiment.

FIG. 6 is a flow diagram illustrating yet another process for testing the PCBA of the diagnostic device according to an embodiment.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as not to unnecessarily obscure the described concepts. While some concepts will be described in conjunction with the specific examples, it will be understood that these examples are not intended to be limiting.

According to some embodiments, test apparatus and method are provided to determine whether a printed circuit board assembly (PCBA) assembled in a diagnostic device (e.g., a pregnancy test device) is suitable for device assembly. The test apparatus can be designed to measure various parameters (e.g., collector current levels) of photo sensors (e.g., photo transistors) when a light source (e.g., light emitting diode (LED)) mounted on the PCBA is powered at a certain voltage (e.g., 3 VDC) and between a range of electrical current levels (e.g., 0.1 mA-1.5 mA). Based on the difference between the collector currents versus irradiance slopes of the photo sensors measured under the operating range of the diagnostic device, the test apparatus can determine whether the PCBA is acceptable or rejectable for device assembly.

In some embodiments, the test apparatus may be operated by a user device running an open-source software (e.g., Tera Term). The user device may be a personal computer (e.g., desktops, laptops, etc.) or a mobile device (e.g., smartphones, tablets, etc.). In an embodiment, a bar code scanner (e.g., QR code scanner) may be connected to the user device to record the codes of PCBA samples (e.g., QR codes) prior to testing. The user device may also be used to log data from the test apparatus (e.g., parameters of photo sensors of the diagnostic device, such as collector current levels, calculated error values between photo sensors, etc.).

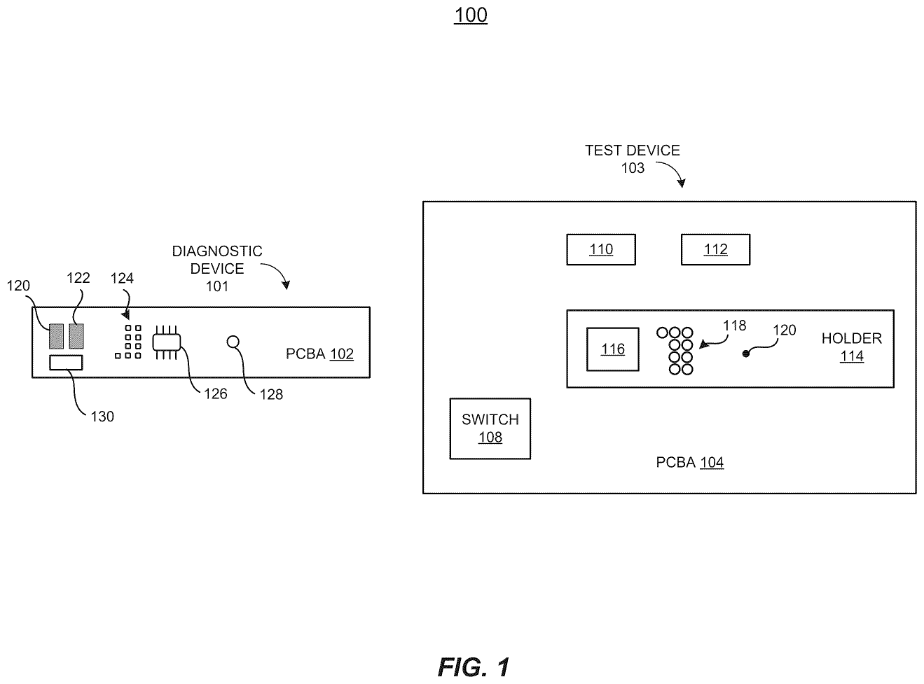

FIG. 1 is a block diagram illustrating an example PCBA test system according to an embodiment. Referring to FIG. 1, PCBA test system 100 includes a diagnostic device 101 and a test device 103. As previously described, the diagnostic device 101 enables a consumer to self-diagnose various medical conditions, for example, pregnancy, ovulation, sexually transmitted infections, and other bacterial infections or clinical abnormalities.

As shown, the diagnostic device 101 may include, but not limited to, a printed circuit board (PCB) or PCBA 102 having a processor (or microcontroller) 126, test pads 124, photo or light sensors 120 and 122, and a light source 130 (e.g., LED) mounted thereon. Light source 130 and photo sensors 120, 122 may be coupled to processor 126. PCBA 102 may further include an alignment hole 128 to receive an alignment pin from the test device 103, as will be described in more detail herein below.

Light source 130 may illuminate a portion of a test strip of the device 101 (not shown). Photo sensor 120 may be positioned to sense an area corresponding to a test result site of the test strip. Photo sensor 122 may be positioned to sense an area adjacent to the test result site of the test strip. Each of the photo sensors 120 and 122 may generate an electrical signal based on the magnitude of the reflected light received by the photo sensor. The electrical signal may be communicated to processor 126 where the signal can be digitized and computed by the processor.

In some embodiments, the processor 126 may receive respective signals from the photo sensors 120 and 122, and perform a comparison of a signal reading of photo sensor 120 and a signal reading of photo sensor 122. The comparison may include a calculation of a difference value by subtracting one of the signal reading of photo sensor 120 and the signal reading of photo sensor 122 from the other of the signal reading of photo sensor 120 and the signal reading of the photo sensor 122. Although not shown, an additional photo sensor may be mounted on PCBA 102 and coupled to processor 126. When this photo sensor detects ambient light, processor 126 may activate the diagnostic device 101 and run a self-diagnostic test to ensure that the device 101 is operating within pre-established parameters.

In an embodiment, the test pads 124 may be connected to a number of terminals of the components on PCBA 102. For example, the test pads may be connected to a terminal of light source 130, terminals of photo sensors 120 and 122, and terminals of other components connected or coupled to processor 126.

With continued reference to FIG. 1, test device 103 is configured to test whether the PCBA 102 assembled in diagnostic device 101 is suitable for device assembly. The test device 103 may set processor 126 to programming mode to disable processor 126, so that the test device 103 can control the diagnostic device 101 and measure various parameters (e.g., collector current levels) of the photo sensors 120 and 122 when the light source 130 is powered at a certain voltage (e.g., 3 VDC) and between a range of electrical current levels (e.g., 0.1 mA-1.5 mA). As shown, test device 103 may include, but not limited to, a PCBA 104 having a start switch 108, a first light source 110 (e.g., LED), a second light source 112 (e.g., LED), and a holder portion 114 mounted thereon.

Start switch 108 may be configured to activate the testing of the PCBA 102. Light source 110 may be illuminated to indicate the test passes and light source 112 may be illuminated to indicate the test fails, or vice versa. Light sources 110 and 112 may emit light of any color (e.g., green, red, etc.). In an embodiment, holder portion 114 is configured to secure the PCBA 102 in place for testing. As shown, holder portion 114 may include, but not limited to, a test cell 116, probes 118 (e.g., spring probes) and an alignment pin 120. In operation, a user/tester may place the PCBA 102 in the holder portion 114 such that the alignment hole 128 effectively receives the alignment pin 120, the light source 130 and photo sensors 120, 122 are aligned within test cell 116, and the test pads 124 are aligned and respectively in contact with the probes 118. In an embodiment, test cell 116 may be formed with white ultraviolet (UV) resistant resin.

Although not shown in FIG. 1, holder portion 114 may be connected to a press arm that provides proper pressure and contact between the test pads 124 and probes 118. When the press arm is in a closed position, the press arm presses against a surface of the PCBA 102 to properly secure the PCBA 102 in holder portion 114. The press arm may include one or more stop portions to prevent over pressing of the PCBA 102 in order to avoid damaging a display (e.g., liquid crystal display) mounted on PCBA 102.

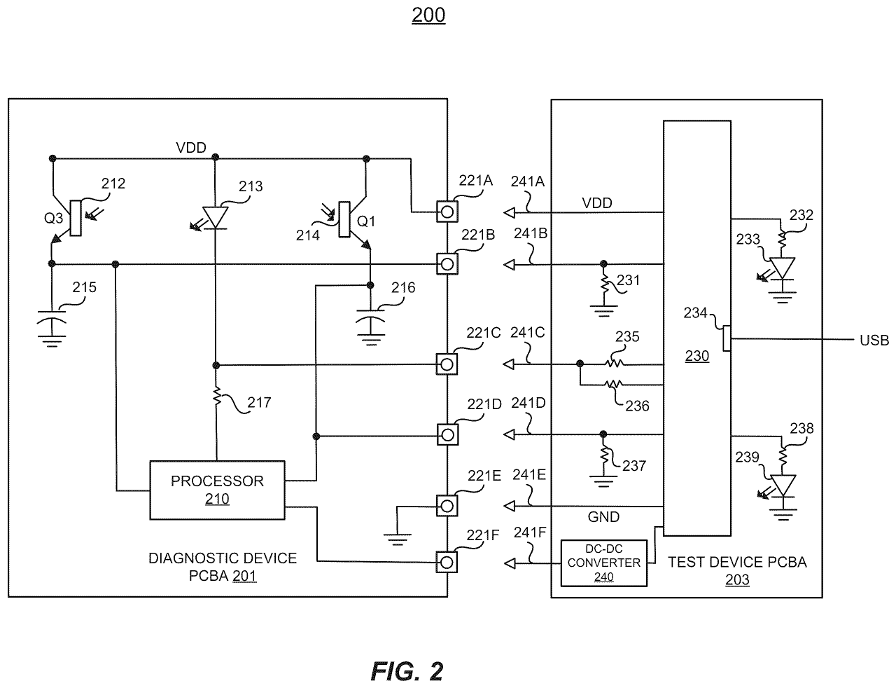

FIG. 2 is a schematic diagram illustrating an example PCBA test system according to an embodiment. Referring to FIG. 2, PCBA test system 200 includes a diagnostic device PCBA 201 and test device PCBA 203. In some embodiments, diagnostic device PCBA 201 and test device PCBA 203 may be the PCBA 102 and PCBA 104 of FIG. 1, respectively. As shown, the diagnostic device PCBA 201 may include, but not limited to, a processor (or microcontroller) 210, photo sensors 212 and 214 (e.g., photo transistors), a light source 213 (e.g., LED), capacitors 215-216, and test pads 221A-F.

In FIG. 2, photo sensor 212 is connected between power supplied by test device PCBA 203 (VDD) and capacitor 215. Similarly, photo sensor 214 is connected between the power supplied by test device PCBA 203 and capacitor 216. In some embodiments, test device PCBA 203 may provide power at 3 volts (V). Processor 210 may be connected to a first terminal of the photo sensor 212 (e.g., emitter terminal) to measure the current flowing through a second terminal of the photo sensor 212 (e.g., collector terminal) and out to the first terminal of the photo sensor 212 (which may be referred to as collector current). Similarly, processor 210 may be connected to a first terminal of the photo sensor 214 (e.g., emitter terminal) to measure the current flowing through a second terminal of the photo sensor 214 (e.g., collector terminal) and out to the first terminal of the photo sensor 214.

In an embodiment, processor 210 may regulate the light source 213 through a current limiting resistor 217 connected in series with the light source 213. For example, when processor 210 outputs a low signal, which may act as a ground GND), light source 213 may draw current from power source 211, with the current being limited to a predetermined value based on a resistance value of the resistor 217. On the other hand, when the processor 210 outputs a high signal, the light source 213 may be turned off or deactivated.

In some embodiments, test pads 221A-F may be respectively connected to a working voltage (VDD) of the diagnostic device PCBA 201, the first terminal of the photo sensor 212, a node between resistor 217 and light source 213, the first terminal of the photo sensor 214, GND, and processor 210. These test pads 221A-F may be connected to the test device PCBA 203 for testing of the PCBA 201 to ensure the PCBA 201 is suitable for device assembly.

With continued reference to FIG. 2, PCBA 203 may include, but not limited to, a processor or microcontroller 230, light sources 233 and 239 (e.g., LEDs) coupled to processor 230 through respective resistors 232 and 238, connection terminals 241A-F for connecting the processor 230 to the test pads 221A-F of PCBA 201, a universal serial bus (USB) port 234 for connecting the processor 230 to a user device, and a DC-DC converter 240. The user device may provide power (e.g., 5V power) to the PCBA 203 through USB port 234, and may also use the USB port 234 to log data from the PCBA 203 (e.g., parameters of photo sensors 212 and 214, such as collector current levels, calculated error values between the photo sensors, etc.).

With continued reference to FIG. 2, PCBA 203 may apply a 13V potential to a master clear (MCLR) pin of processor 210 after 3V VDD power is supplied. This targeted application of 13V, generated by the onboard DC-DC converter 240 within test device PCBA 203, may initiate a specific mode of operation within processor 210, which may be referred to as “programming” mode. When in this mode, the input/output (I/O) pins of processor 210 may be rendered into a high-impedance state. This condition effectively isolates the processor 210 from the remainder of the circuit of PCBA 201, thereby preventing any interference from the processor's signals during the testing phase.

As illustrated in FIG. 2, terminal 241A may be connected to a VDD of the test device PCBA 203 and terminal 241E may be connected to GND. Terminal 241B may be connected to resistor 231 and test pad 221B to measure a collector current flowing out to the first terminal of the photo sensor 212. Similarly, terminal 241D may be connected to resistor 237 and test pad 221D to measure a collector current flowing out to the first terminal of the photo sensor 214. Terminal 241C may be connected to test pad 221C and configured to regulate the current drawn by light source 213. For example, processor 230 may send a low signal through one or both of current limiting resistors 235-236 (which may act as a current divider) connected to the terminal 241C, to power the light source 213 at different predetermined current levels, such as a low current level (e.g., 0.1 mA-0.5 mA) and a high current level (e.g., 1 mA-1.5 mA). The light source 213 emits a light intensity in accordance with the predetermined current levels controlled by the processor 230. The collector current of each photo sensor may vary based on the predetermined current levels and the light intensity detected by the photo sensor via a third terminal (e.g., a base terminal of the photo sensor).

Based on the measured collector currents of the photo sensors 212 and 214, processor 230 may calculate an error value (e.g., an absolute percentage error value). The processor 230 may compare the error value to a predetermined threshold (e.g., a maximum allowable percentage error). If the error value is below the predetermined threshold, the processor 230 may send a signal to illuminate the light source 233 to indicate a pass in the test. Otherwise, the processor 230 may send a signal to illuminate the light source 239 to indicate the test has failed.

In some embodiments, the diagnostic device 101 may be faulty, or it may not be properly seated in the test device 103, resulting in a poor or missing connection between one or more terminals 241A-F and the corresponding test pads 221A-F. In this case, little or no voltage may be present on terminal 241B or 241D. Processor 230 may detect this condition and send signals to illuminate both light sources 233 and 239, indicating that the diagnostic device 101 or diagnostic device PCBA 201 was not found.

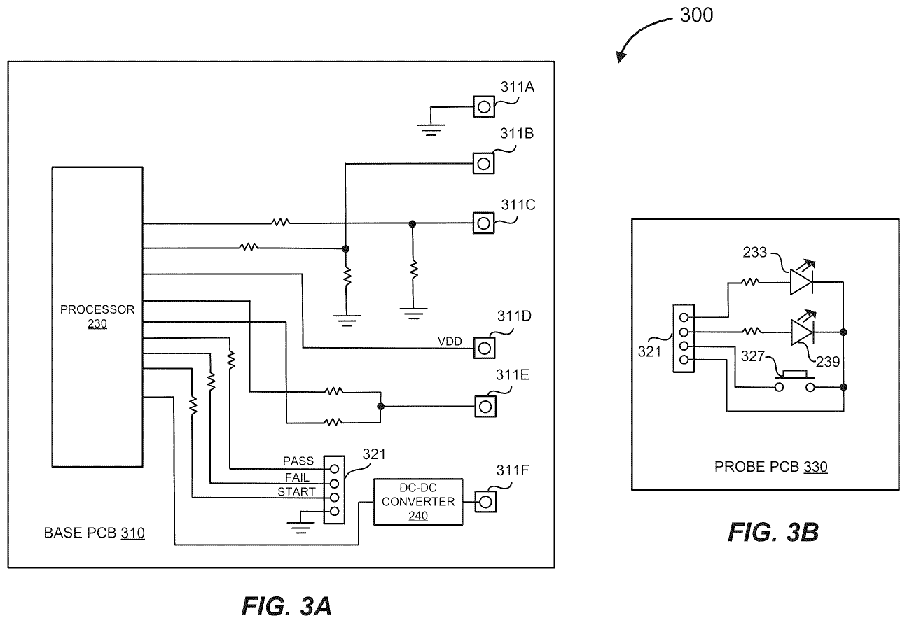

FIGS. 3A-3B are schematic diagrams of a PCBA of a test device according to an embodiment. In some embodiments, PCBA 300 may be test device PCBA 203 of FIG. 2. Referring to FIGS. 3A-3B, PCBA 300 may include a base (or bottom) PCB 310 and a probe (or top) PCB 330. Base PCB 310 may include the processor 230 connected or coupled to probes 331A-E (e.g., spring or contact probes) and PCB header 321.

Probes 311A-F may be configured to create contact between the terminals 241A-F of FIG. 2 and test pads 221A-F of FIG. 2. For example, probe 311A may be configured to connect terminal 241E (GND) to test pad 221E, and probe 311D may be configured to connect terminal 241A (VDD) to test pad 221A. Probe 311B may be configured to connect terminal 241D to test pad 221D, and probe 311C may be configured to connect terminal 241B to test pad 221B. Probe 311E may be configured to connect terminal 241C to test pad 221C, and finally, probe 311F may be configured to connect terminal 241F to test pad 221F. PCB header 321 is configured to join the connections between the base PCB 310 and probe PCB 330. For example, as shown, PCB header 321 may be configured to connect or couple the processor 230 to light sources 233, 239 and start switch 327.

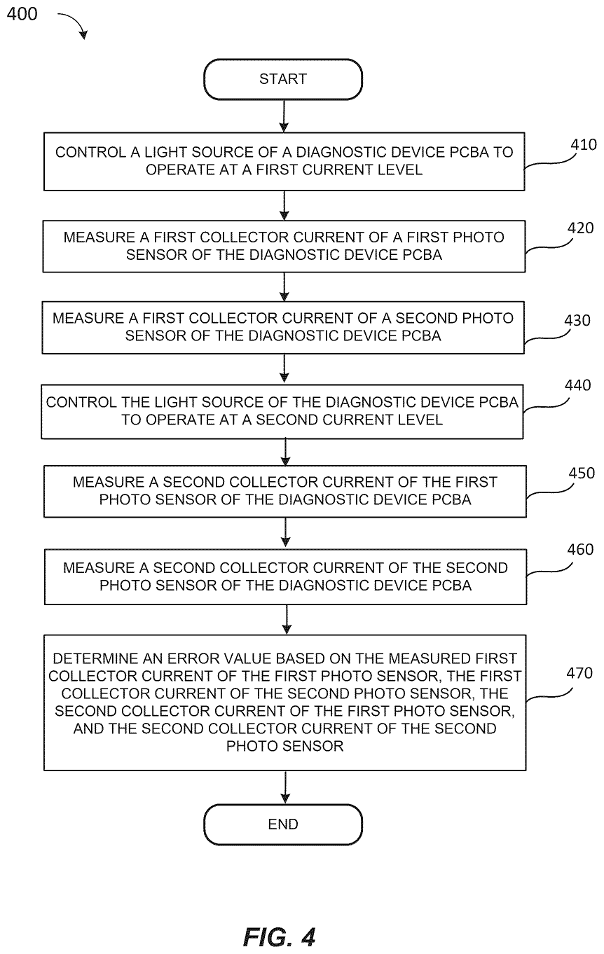

FIG. 4 is a flow diagram illustrating a process for testing a PCBA of a diagnostic device according to an embodiment. Process 400 may be performed by processing logic which may include software, hardware, or a combination thereof. For example, process 400 may be performed by processor 230 of FIG. 2.

Referring to FIG. 4, at block 410, the processing logic may control a light source of a diagnostic device PCBA (e.g., light source 213 of FIG. 2) to operate at a first current level (e.g., 0.1 mA-0.5 mA). For example, the processing logic may send a low signal, which may act as a GND, to current limiting resistors (e.g., resistors 235-236 of FIG. 2) to control the light source to operate at the first current level.

At block 420, the processing logic may measure a first collector current of a first photo sensor (e.g., photo sensor 214) of the diagnostic device PCBA. For example, the processing logic may measure the current flowing through the second terminal of the photo sensor 214 and out to the first terminal of the photo sensor 214 via probe 311B while the light source is emitting light at the first current level. In some embodiments, the processing logic may store the measured first collector current of the first photo sensor as a first collector current value/level in a storage device of the test PCBA (e.g., flash memory) coupled to the processor 230.

At block 430, the processing logic may measure a first collector current of a second photo sensor (e.g., photo sensor 212) of the diagnostic device PCBA. For example, the processing logic may measure the current flowing through the second terminal of the photo sensor 212 and out to the first terminal of the photo sensor 212 via probe 311C while the light source is emitting light at the first current level. In some embodiments, the processing logic may store the measured first collector current of the second photo sensor as a second collector current value/level in the storage device.

At block 440, the processing logic may control the light source to operate at a second current level (e.g., 1 mA-1.5 mA). The second current level may be higher than the first current level. For example, the processing logic may send a low signal, which may act as a GND, to one of the current limiting resistors to control the light source to operate at the second current level.

At block 450, the processing logic may measure a second collector current of the first photo sensor of the diagnostic device PCBA. For example, the processing logic may measure the current flowing through the second terminal of the photo sensor 214 and out to the first terminal of the photo sensor 214 via probe 311B while the light source is emitting light at the second current level. In some embodiments, the processing logic may store the measured second collector current of the first photo sensor as a third collector current value/level in the storage device.

At block 460, the processing logic may measure a second collector current of the second photo sensor of the diagnostic device PCBA. For example, the processing logic may measure the current flowing through the second terminal of the photo sensor 212 and out to the first terminal of the photo sensor 212 via probe 311C while the light source is emitting light at the second current level. In some embodiments, the processing logic may store the measured second collector current of the second photo sensor as a fourth collector current value/level in the storage device.

At block 470, the processing logic may determine an error value (e.g., an absolute percentage error value) based on the measured first collector current of the first photo sensor (I_{Q1_Low}), the first collector current of the second photo sensor (I_{Q3_Low}), the second collector current of the first photo sensor (I_{Q1}), and the second collector current of the second photo sensor (I_{Q3}). For example, the processing logic may determine the error value (Pct_Err) as:

$$\vert Pct\_Err \vert = ( 100 * ( {I}_{Q 3\_ Low} / {I}_{Q 3} ) ) - ( 100 * ( {I}_{Q 1 \_ Low} / {I}_{Q 1} ) ) ,$$

where |Pct_Err| is an absolute value of the error value. As one of ordinary skill in the art would appreciate, an absolute value of a value is the non-negative value of the value without regard to its sign.

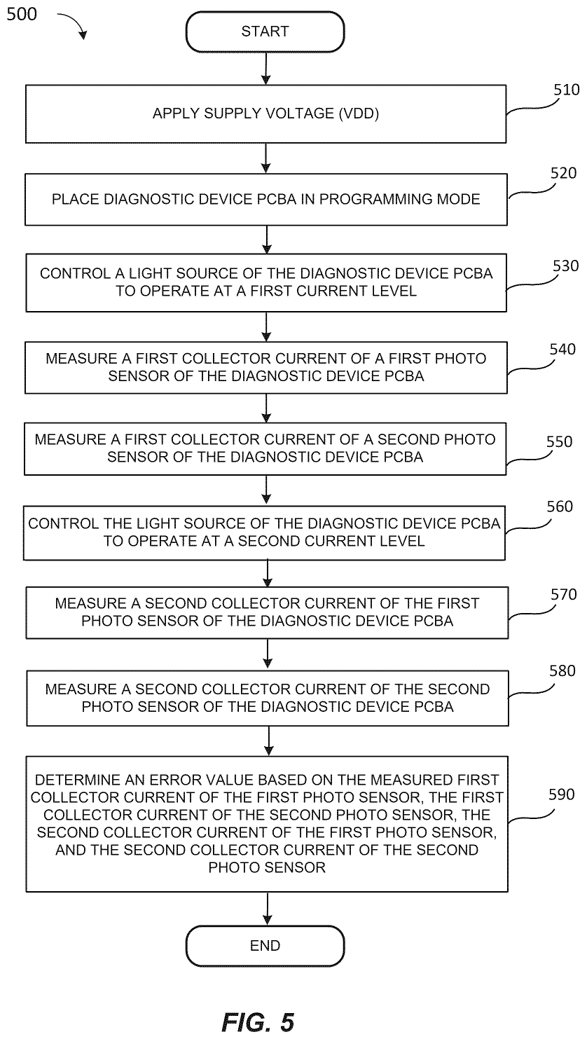

FIG. 5 is a flow diagram illustrating another process for testing the PCBA of the diagnostic device according to an embodiment. Process 500 may be performed by processing logic which may include software, hardware, or a combination thereof. For example, process 500 may be performed by processor 230 of FIG. 2.

At block 510, the processing logic may apply a supply voltage (e.g., 3V VDD) to power the diagnostic device PCBA. For example, the processing logic may apply the supply voltage to test pad 221A of diagnostic device PCBA 201 when it is connected to terminal 241A (VDD) of the test device PCBA 203.

At block 520, the processing logic may place the diagnostic device PCBA in programming mode. For example, the processing logic may apply a 13V potential, generated by DC-DC converter 240 of test device PCBA 203, to a master clear (MCLR) pin of processor 210 of diagnostic device PCBA 201 to switch the processor 210 into programming mode, effectively disabling and isolating the processor 210 from the remainder of the circuit under test. As previously described, when operating in programming mode, the input/output (I/O) pins of processor 210 may be rendered into a high-impedance state. This condition effectively isolates the processor 210 from the remainder of the circuit of PCBA 201, thereby preventing any interference from the processor's signals during the testing phase. This enables the processing logic to perform the subsequent operations in blocks 530-590 of FIG. 5.

With respect to blocks 530-590, those operations described therein are similar to or same as the operations previously described in blocks 410-470 of FIG. 4. Accordingly, for brevity sake, the operations of blocks 530-590 will not be described herein.

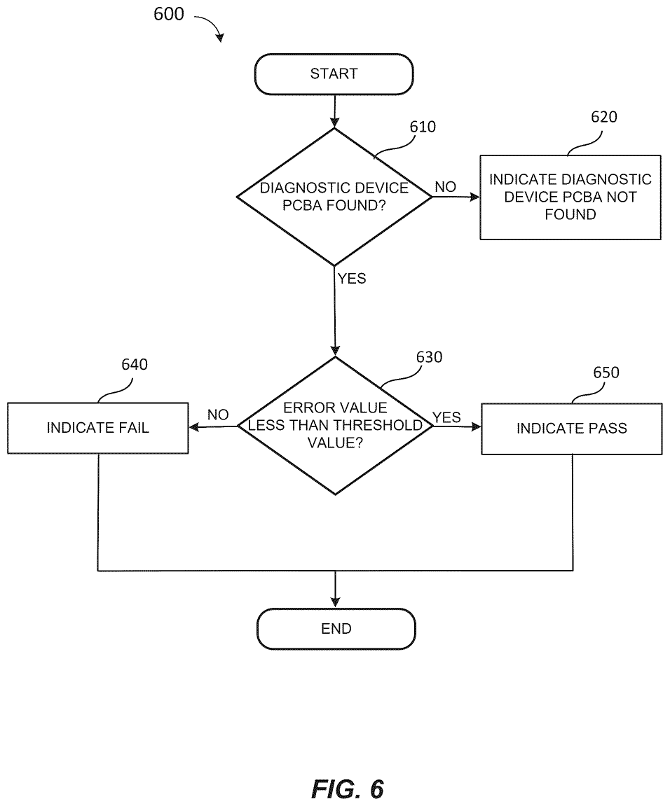

FIG. 6 is a flow diagram illustrating yet another process for testing the PCBA of the diagnostic device according to an embodiment. Process 600 may be performed by processing logic which may include software, hardware, or a combination thereof. For example, process 600 may be performed by processor 230 of FIG. 2.

Referring to FIG. 6, at block 610, the processing logic may determine whether the diagnostic device PCBA was found. For example, if any of the sensor readings (e.g., through probes 311A-F) is below a certain threshold, the processing logic may determine that the diagnostic device PCBA was not found. Accordingly, at block 620, the processing logic may indicate that the diagnostic device PCBA was not found, for example, by illuminating both pass and fail light sources (e.g., light sources 233 and 239 of FIG. 2) simultaneously.

Otherwise, if it is determined that the diagnostic device PCBA was found, at block 630, the processing logic determines whether the error value (e.g., absolute error value) is less than a threshold value. The threshold value may be a maximum allowable percentage error predetermined by a user or tester (e.g., 1%).

At block 650, if it is determined that the error value is less than the threshold value, the processing logic indicates a pass. For example, the processing logic may send an electrical signal to illuminate a light source (e.g., light source 233 of FIG. 2) of a certain color (e.g., green).

Otherwise, if it is determined that the error value is greater than or equal to the threshold value, at block 640, the processing logic indicates a failure. For example, the processing logic may send an electrical signal to illuminate another light source (e.g., light source 239 of FIG. 2) of certain color (e.g., red).

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the disclosure also relate to an apparatus for performing the operations herein. Such a computer program is stored in a non-transitory computer readable medium. A machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments of the present disclosure are not described with reference to any particular programming language. It will be appreciated that a variety of programming languages may be used to implement the teachings of embodiments of the disclosure as described herein.

In the foregoing specification, embodiments of the disclosure have been described with reference to specific example embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A test apparatus for testing a printed circuit board assembly (PCBA) of a diagnostic device, the test apparatus comprising:
a processor; and
a memory coupled to the processor to store instructions, which when executed by the processor, cause the test apparatus to:
control a light source of the PCBA of the diagnostic device to operate at a first current level;
measure a first collector current of a first photo sensor of the PCBA of the diagnostic device;
measure a first collector current of a second photo sensor of the PCBA of the diagnostic device;
control the light source of the PCBA of the diagnostic device to operate at a second current level;
measure a second collector current of the first photo sensor of the PCBA of the diagnostic device;
measure a second collector current of the second photo sensor of the PCBA of the diagnostic device; and
determine an error value based on the measured first collector current of the first photo sensor, the measured first collector current of the second photo sensor, the measured second collector current of the first photo sensor, and the measured second collector current of the second photo sensor.

2. The test apparatus of claim 1, wherein the instructions, which when executed by the processor, further cause the test apparatus to:
determine whether the error value is less than a threshold value, wherein the error value is an absolute error value;
in response to determining that the error value is less than the threshold value, send a first signal to illuminate a first light source of the test apparatus to indicate a pass.

3. The test apparatus of claim 2, wherein the instructions, which when executed by the processor, further cause the test apparatus to:
in response to determining that the error value is greater than or equal to the threshold value, send a second signal to illuminate a second light source of the test apparatus to indicate a failure.

4. The test apparatus of claim 1, wherein the instructions, which when executed by the processor, further cause the test apparatus to:
store the measured first collector current of the first photo sensor as a first collector current value;
store the measured first collector current of the second photo sensor as a second collector current value;
store the measured second collector current of the first photo sensor as a third collector current value; and
store the measured second collector current of the second photo sensor as a fourth collector current value.

5. The test apparatus of claim 4, wherein to determine the error value, the instructions, which when executed by the processor, cause the test apparatus to:
determine the error value in accordance with the following:
$$\vert Pct\_Err \vert = ( 100 * ( {I}_{Q 3\_ Low} / {I}_{Q 3} ) ) - ( 100 * ( {I}_{Q 1 \_ Low} / {I}_{Q 1} ) ) ;$$
wherein:

|Pct_Err| is an absolute value of the error value;
I_{Q1_Low} is the first collector current value;
I_{Q3_Low} is the second collector current value;
I_{Q1} is the third collector current value; and
I_{Q3} is the fourth collector current value.

6. The test apparatus of claim 1, wherein the second current level is higher than the first current level.

7. The test apparatus of claim 1, wherein the instructions, which when executed by the processor, further cause the test apparatus to:
apply a supply voltage to the PCBA of the diagnostic device; and
apply a voltage potential to a processor or microcontroller on the PCBA of the diagnostic device to switch the processor or microcontroller on the PCBA of the diagnostic device to a programming mode.

8. A non-transitory machine-readable medium having instructions stored therein, which when executed by a processor, cause the processor to perform operations, the operations comprising:
controlling a light source of a printed circuit board assembly (PCBA) of a diagnostic device to operate at a first current level;
measuring a first collector current of a first photo sensor of the PCBA of the diagnostic device;
measuring a first collector current of a second photo sensor of the PCBA of the diagnostic device;
controlling the light source of the PCBA of the diagnostic device to operate at a second current level;
measuring a second collector current of the first photo sensor of the PCBA of the diagnostic device;
measuring a second collector current of the second photo sensor of the PCBA of the diagnostic device; and
determining an error value based on the measured first collector current of the first photo sensor, the measured first collector current of the second photo sensor, the measured second collector current of the first photo sensor, and the measured second collector current of the second photo sensor.

9. The non-transitory machine-readable medium of claim 8, wherein the operations further comprise:
determining whether the error value is less than a threshold value, wherein the error value is an absolute error value;
in response to determining that the error value is less than the threshold value, sending a first signal to illuminate a first light source of a test apparatus to indicate a pass.

10. The non-transitory machine-readable medium of claim 9, wherein the operations further comprise:
in response to determining that the error value is greater than or equal to the threshold value, sending a second signal to illuminate a second light source of the test apparatus to indicate a failure.

11. The non-transitory machine-readable medium of claim 8, wherein the operations further comprise:
storing the measured first collector current of the first photo sensor as a first collector current value;
storing the measured first collector current of the second photo sensor as a second collector current value;
storing the measured second collector current of the first photo sensor as a third collector current value; and
storing the measured second collector current of the second photo sensor as a fourth collector current value.

12. The non-transitory machine-readable medium of claim 11, wherein determining the error value comprises:
determining the error value in accordance with the following:
$$\vert Pct\_Err \vert = ( 100 * ( {I}_{Q 3\_ Low} / {I}_{Q 3} ) ) - ( 100 * ( {I}_{Q 1 \_ Low} / {I}_{Q 1} ) ) ;$$
wherein:

|Pct_Err| is an absolute value of the error value;
I_{Q1_Low} is the first collector current value;
I_{Q3_Low} is the second collector current value;
I_{Q1} is the third collector current value; and
I_{Q3} is the fourth collector current value.

13. The non-transitory machine-readable medium of claim 8, wherein the second current level is higher than the first current level.

14. The non-transitory machine-readable medium of claim 8, wherein the operations further comprise:
applying a supply voltage to the PCBA of the diagnostic device; and
applying a voltage potential to a processor or microcontroller on the PCBA of the diagnostic device to switch the processor or microcontroller on the PCBA of the diagnostic device to a programming mode.

15. A computer-implemented method of testing a printed circuit board assembly (PCBA) of a diagnostic device, the method comprising:
controlling a light source of the PCBA of the diagnostic device to operate at a first current level;
measuring a first collector current of a first photo sensor of the PCBA of the diagnostic device;
measuring a first collector current of a second photo sensor of the PCBA of the diagnostic device;
controlling the light source of the PCBA of the diagnostic device to operate at a second current level;
measuring a second collector current of the first photo sensor of the PCBA of the diagnostic device;
measuring a second collector current of the second photo sensor of the PCBA of the diagnostic device; and
determining an error value based on the measured first collector current of the first photo sensor, the measured first collector current of the second photo sensor, the measured second collector current of the first photo sensor, and the measured second collector current of the second photo sensor.

16. The method of claim 15, further comprising:
determining whether the error value is less than a threshold value, wherein the error value is an absolute error value;
in response to determining that the error value is less than the threshold value, sending a first signal to illuminate a first light source of a test apparatus to indicate a pass.

17. The method of claim 16, further comprising:
in response to determining that the error value is greater than or equal to the threshold value, sending a second signal to illuminate a second light source of the test apparatus to indicate a failure.

18. The method of claim 15, further comprising:
storing the measured first collector current of the first photo sensor as a first collector current value;
storing the measured first collector current of the second photo sensor as a second collector current value;
storing the measured second collector current of the first photo sensor as a third collector current value; and
storing the measured second collector current of the second photo sensor as a fourth collector current value.

19. The method of claim 18, wherein determining the error value comprises:
determining the error value in accordance with the following:
$$\vert Pct\_Err \vert = ( 100 * ( {I}_{Q 3\_ Low} / {I}_{Q 3} ) ) - ( 100 * ( {I}_{Q 1 \_ Low} / {I}_{Q 1} ) ) ;$$
wherein:

|Pct_Err| is an absolute value of the error value;
I_{Q1_Low} is the first collector current value;
I_{Q3_Low} is the second collector current value;
I_{Q1} is the third collector current value; and
I_{Q3} is the fourth collector current value.

20. The method of claim 15, further comprising:
applying a supply voltage to the PCBA of the diagnostic device; and
applying a voltage potential to a processor or microcontroller on the PCBA of the diagnostic device to switch the processor or microcontroller on the PCBA of the diagnostic device to a programming mode.
